(19) United States
(12) Patent Application Publication
(10) Pub. No.: US 2025/0174432 A1
(43) Pub. Date: May 29, 2025

(54) INDUCTIVE COUPLED COIL, RADIO FREQUENCY PROVISION APPARATUS, RADIO FREQUENCY CONTROL METHOD, AND DEVICE

(71) Applicant: JIANGSU LEUVEN INSTRUMENTS CO., LTD, Xuzhou, Jiangsu (CN)

(72) Inventors: Haiyang LIU, Xuzhou, Jiangsu (CN); Xiaobo LIU, Xuzhou, Jiangsu (CN); Shuai CHEN, Xuzhou, Jiangsu (CN); Song GUO, Xuzhou, Jiangsu (CN); Chengyi WANG, Xuzhou, Jiangsu (CN); Xiao ZHANG, Xuzhou, Jiangsu (CN); Dongdong HU, Xuzhou, Jiangsu (CN); Kaidong XU, Xuzhou, Jiangsu (CN)

(73) Assignee: JIANGSU LEUVEN INSTRUMENTS CO., LTD., Xuzhou, Jiangsu (CN)

(21) Appl. No.: 18/720,404

(22) PCT Filed: Nov. 25, 2022
(86) PCT No.: PCT/CN2022/134506

§ 371 Date: Jun. 14, 2024

(30) Foreign Application Priority Data
Dec. 17, 2021 (CN) 202111556207.3

(51) Int. Cl. H01J 37/32; H01F 27/29

(52) U.S. Cl. CPC H01J 37/3211; H01F 27/29

(57) ABSTRACT

An inductive coupling coil is provided, including an inner coil, a middle coil, an outer coil and a first variable capacitor. The middle coil surrounds the inner coil, and the outer coil surrounds the middle coil. The inner coil and the middle coil are connected in series in a first path. A first terminal of the first path is configured to be connected to a radio frequency power source, and a second terminal of the first path is configured to be connected to ground. The middle coil is connected to the first variable capacitor in parallel. The outer coil is in a second path. A first terminal of the second path is configured to be connected to the radio frequency power source, and a second terminal of the second path is configured to be connected to the ground.

The present application claims the priority to Chinese Patent Application No. 202111556207.3, titled “INDUCTIVE COUPLED COIL, RADIO FREQUENCY PROVISION APPARATUS, RADIO FREQUENCY CONTROL METHOD, AND DEVICE”, filed with the China National Intellectual Property Administration on Dec. 17, 2021, which is incorporated herein by reference in its entirety.

### FIELD

The present disclosure relates to the technical field of semiconductor devices and manufacturing thereof, and in particular to an inductive coupling coil, a radio frequency apparatus, a radio frequency control method, and a plasma processing device.

### BACKGROUND

In the manufacturing process of semiconductor devices, a plasma processing is a key process for patterning wafers. In a typical plasma processing, a process gas is excited by a radio frequency (RF) to form plasma. The plasma physically bombards and chemically reacts with a surface of a wafer under the action of an electrical field between an upper electrode and a lower electrode, to process the surface of the wafer.

At present, non-volatile materials such as Pt, Ru, Ir, Ni, Fe and Au are dry-etched mainly by inductive coupled plasma (ICP). The inductive coupled plasma is usually generated by an inductive coupling coil, which is arranged outside a plasma chamber and is adjacent to a dielectric window. The inductive coupling coil is connected to a radio frequency power source, and radio frequency power from the radio frequency power source drives the inductive coupling coil to generate a strong high-frequency alternating magnetic field, such that the process gas in the chamber is ignited to form the plasma.

The use of the inductive coupled plasma can easily cause nonuniform etching of the wafer, even resulting in reducing of the wafer yield.

### SUMMARY

In view of this, an inductive coupling coil, a radio frequency apparatus, a radio frequency control method, and a plasma processing device are provided according to embodiments of the present disclosure, to improve uniformity of wafer etching.

The following technical solutions are provided according to the present disclosure.

An inductive coupling coil is provided according to embodiments of the present disclosure. The inductive coupling coil includes an inner coil, a middle coil, an outer coil and a first variable capacitor, where
the middle coil surrounds the inner coil, and the outer coil surrounds the middle coil;
the inner coil and the middle coil are connected in series in a first path;
a first terminal of the first path is configured to be connected to a radio frequency power source, and a second terminal of the first path is configured to be connected to ground;
the middle coil is connected to the first variable capacitor in parallel;
the outer coil is in a second path; and
a first terminal of the second path is configured to be connected to the radio frequency power source, and a second terminal of the second path is configured to be connected to the ground.

In an embodiment, the inductive coupling coil further includes a second variable capacitor and a third variable capacitor, where
the second variable capacitor is in the first path and is connected to the inner coil and the middle coil in series; and
the third variable capacitor is in the second path and is connected to the outer coil in series.

In an embodiment, the inductive coupling coil further includes a first current transformer and a second current transformer, where
the first current transformer is in the first path and is connected to the inner coil and the middle coil in series; and
the second current transformer is in the second path and is connected to the outer coil in series.

In an embodiment, the inductive coupling coil further includes a first ground capacitor and a second ground capacitor, where
the first ground capacitor is in the first path and is connected to the inner coil and the middle coil in series; and
the second ground capacitor is in the second path and is connected to the outer coil in series.

In an embodiment, the inductive coupling coil further includes a first additional coil, where
the first additional coil is in the first path and is connected to the inner coil and the middle coil in series; and
the first additional coil surrounds the inner coil and is surrounded by the middle coil, or the first additional coil surrounds the middle coil and is surrounded by the outer coil.

In an embodiment, the inductive coupling coil further includes a second additional coil, where
the second additional coil is in the first path and is connected to the middle coil in parallel; and
the second additional coil surrounds the inner coil and is surrounded by the middle coil, or the second additional coil surrounds the middle coil and is surrounded by the outer coil.

A radio frequency apparatus is provided according to embodiments of the present disclosure. The radio frequency apparatus includes the inductive coupling coil, a radio frequency power source and a ground terminal, where
the radio frequency power source is configured to provide a radio frequency signal to the first terminal of the first path and the first terminal of the second path; and
the ground terminal is configured to connect the second terminal of the first path and the second terminal of the second path to the ground.

In an embodiment, power of the inner coil is lower than power of the outer coil.

A radio frequency control method is provided according to embodiments of the present disclosure. The method includes: controlling the first variable capacitor of the inductive coupling coil to control power of the middle coil.

A plasma processing device is provided according to embodiments of the present disclosure. The device includes a wafer holding apparatus, a process gas generating apparatus and the radio frequency apparatus, where
the wafer holding apparatus is configured to hold a wafer to be processed;
the process gas generating apparatus is configured to provide a process gas; and
the radio frequency apparatus is configured to generate a high-frequency alternating magnetic field, such that the process gas forms plasma to process the wafer to be processed.

An inductive coupling coil, a radio frequency apparatus, a radio frequency control method and a plasma processing device are provided in the embodiments of the present disclosure. The inductive coupling coil includes an inner coil, a middle coil, an outer coil and a first variable capacitor. The middle coil surrounds the inner coil, and the outer coil surrounds the middle coil. The inner coil and the middle coil are connected in series in a first path. A first terminal of the first path is connected to a radio frequency power source, and a second terminal of the first path is connected to ground. The outer coil is in a second path. A first terminal of the second path is connected to the radio frequency power source, and a second terminal of the second path is connected to the ground. That is, the inner coil and the middle coil are connected in series to form a branch, and the branch is connected to the outer coil in parallel. The middle coil is connected to the first variable capacitor in parallel. In this way, power of the middle coil is reduced, thereby reducing an etching rate in a region between the inner coil and the outer coil, and thus improving the uniformity of wafer etching.

### BRIEF DESCRIPTION OF THE DRAWINGS

In order to illustrate technical solutions in embodiments of the present disclosure or in the conventional technology more clearly, drawings used for describing the embodiments or the conventional technology will be briefly described hereinafter. Apparently, the drawings in the following description show only some examples of the present disclosure, and for those skilled in the art, other drawings may be obtained based on these drawings without any creative efforts.

FIG. 1 is a schematic diagram showing an etching rate of a wafer in the conventional technology;

FIG. 2 is a schematic diagram showing an etching rate of another wafer in the conventional technology;

FIG. 3 is a schematic diagram showing a structure of an inductive coupling coil according to an embodiment of the present disclosure;

FIG. 4 is a schematic diagram showing a circuit of an inductive coupling coil according to an embodiment of the present disclosure;

FIG. 5 is a schematic diagram showing a three-dimensional structure of an inductive coupling coil according to an embodiment of the present disclosure;

FIG. 6 is a schematic diagram showing an etching rate of a wafer according to an embodiment of the present disclosure;

FIG. 7 is a schematic diagram showing a circuit of another inductive coupling coil according to an embodiment of the present disclosure; and

FIG. 8 is a schematic diagram showing a circuit of yet another inductive coupling coil according to an embodiment of the present disclosure.

### DETAILED DESCRIPTION OF THE EMBODIMENTS

The embodiments of the present disclosure will be described in detail as follows in conjunction with the accompany drawings, so that purposes, characteristics and advantages of the present disclosure become more obvious and understandable.

Many specific details are described in the following description to facilitate a full understanding of the present disclosure. However, the present disclosure can be implemented in other ways different from those described herein, and similar modifications may be made by those skilled in the art without departing from the connotation of the present disclosure. Therefore, the present disclosure is not limited by the specific embodiments disclosed hereinafter.

The present disclosure is described in detail in conjunction with the schematic drawings. When the embodiments of the present disclosure are described in detail, for facilitating description, the cross-sectional view of the structure of the devices may be partially enlarged out of proportion, and the schematic diagram is only schematic, which should not limit the protection scope of the present disclosure. In addition, three-dimensional sizes including a length, a width and a depth should be included in actual manufacturing.

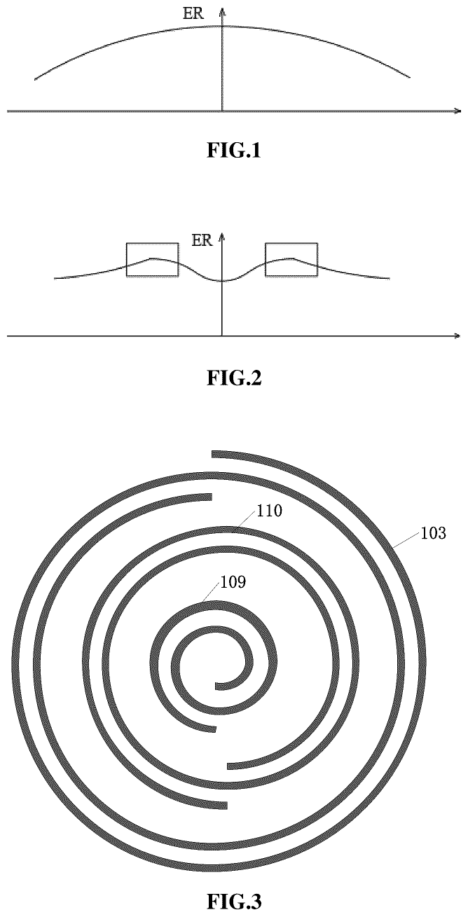

Currently, inductive coupled plasma is used for wafer etching. In fact, this etching method can easily cause nonuniform etching of the wafer, even resulting in reducing of the wafer yield. This is because voltages and capacities of different parts of an inductive coupling coil are coupled to the plasma. The coupling causes nonuniform etching of the wafer, although it facilitates igniting and stabilizing the plasma. Reference is made to FIG. 1, which is a schematic diagram showing an etching rate of a wafer in the conventional technology. A horizontal axis shows a distance to a center of the wafer. An origin shows a center position on the wafer, and a vertical axis shows an etching rate. It can be seen from FIG. 1 that, an etching rate at the center position on the wafer is highest, and an etching rate at an edge position on the wafer is lowest.

To balance the etching rates at the center position and the edge position on the wafer, the inductive coupling coil can be divided into an inner coil and an outer coil in the conventional technology, where the outer coil surrounds the inner coil. The outer coil is located at the edge position on the wafer, and the inner coil is located at the center position on the wafer. A plasma concentration in a chamber, which is affected by the inductive coupling coil, is adjusted by adjusting power distributed to the inner coil and the outer coil, so as to increase the etching rate at different positions on the wafer. However, with this method, the inner coil and the outer coil may affect each other, resulting in that the etching rates at some positions on the wafer cannot be adjusted as expected.

Reference is made to FIG. 2, which is a schematic diagram showing an etching rate of another wafer in the conventional technology. It can be seen that, when power of the inner coil decreases and power of the outer coil increases, the etching rate at the center position on the wafer is reduced, the etching rate at the edge position on the wafer is increased, and the uniformity of the etching rate is improved to some degree. Nevertheless, the plasma concentration in a region between the inner coil and the outer coil is affected by both the inner coil and the outer coil, and thus an etching rate at a position (shown by the blocks) on the wafer corresponding to this region is affected. As a result, the etching rate at the position cannot be reduced as expected, resulting in that adjustment of the uniformity of the wafer is limited.

Based on this, an inductive coupling coil, a radio frequency apparatus, a radio frequency control method and a plasma processing device are provided in the embodiments of the present disclosure. The inductive coupling coil includes an inner coil, a middle coil, an outer coil and a first variable capacitor. The middle coil surrounds the inner coil, and the outer coil surrounds the middle coil. The inner coil and the middle coil are connected in series in a first path. A first terminal of the first path is connected to a radio frequency power source, and a second terminal of the first path is connected to ground. The outer coil is in a second path. A first terminal of the second path is connected to the radio frequency power source, and a second terminal of the second path is connected to the ground. That is, the inner coil and the middle coil are connected in series to form a branch, and the branch is connected to the outer coil in parallel. The middle coil is connected to the first variable capacitor in parallel. In this way, the power of the middle coil is reduced, thereby reducing an etching rate in the region between the inner coil and the outer coil, and thus improving the uniformity of wafer etching.

For better understanding of technical solutions and technical effects of the present disclosure, specific embodiments will be described in detail in conjunction with drawings hereinafter.

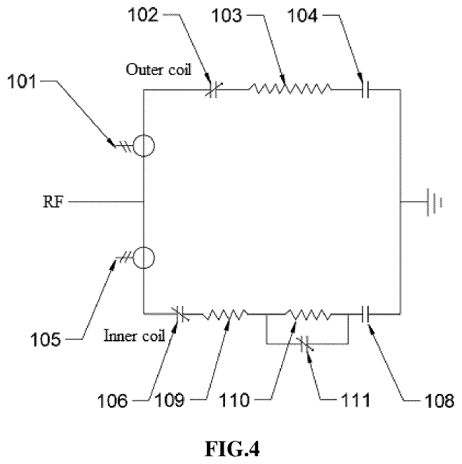

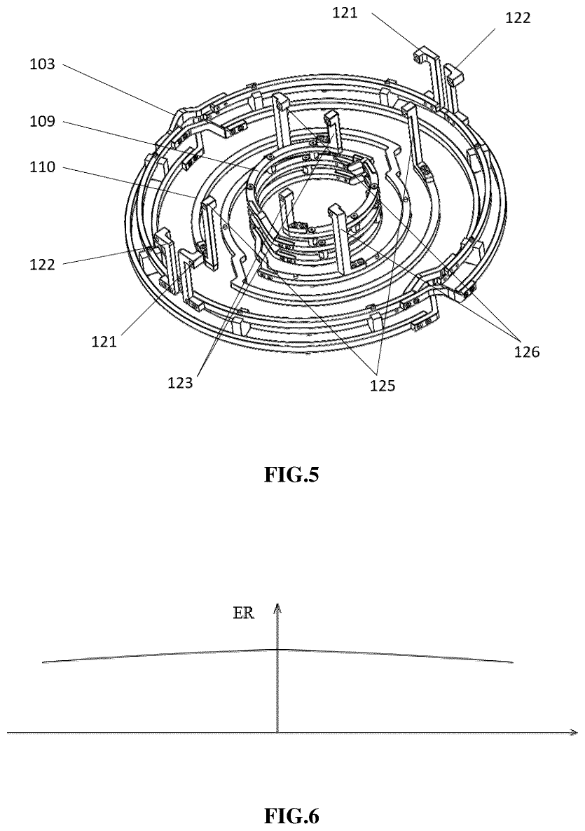

An inductive coupling coil is provided in embodiments of the present disclosure. Reference is made to FIG. 3, which is a schematic diagram showing a structure of an inductive coupling coil according to an embodiment of the present disclosure. Reference is made to FIG. 4, which is a schematic diagram showing a circuit of an inductive coupling coil according to an embodiment of the present disclosure. The inductive coupling coil includes an inner coil, a middle coil, an outer coil and a first variable capacitor.

The inner coil 109 is located in a center region corresponding to a center position on the wafer. The middle coil 110 surrounds the inner coil 109, and is located at a middle position between the center position and an edge position on the wafer. The outer coil 103 surrounds the middle coil 110, and is located at the edge position on the wafer.

The outer coil 103 may be in a second path. A first terminal of the second path is connected to a radio frequency power source (RF), and a second terminal of the second path is connected to ground. In this way, when the inductive coupling coil is connected to the radio frequency power source and the ground, the radio frequency power source provides a radio frequency signal to the outer coil 103, and thus plasma is generated at the edge position on the wafer to process the edge position on the wafer.

The inner coil 109 and the middle coil 110 are connected in series in a first path. A first terminal of the first path is connected to the radio frequency power source, and a second terminal of the first path is connected to ground. In this way, when the inductive coupling coil is connected to the radio frequency power source and the ground, the radio frequency power source provides a radio frequency signal to the inner coil 109 and the middle coil 110, and thus plasma is generated at the center position and at a middle position between the center position and the edge position, to process these positions on the wafer. Since the inner coil 109 and the middle coil 110 are connected in series, a voltage is divided by the inner coil 109 and the middle coil 110. In this way, power of the inner coil 109 is decreased, thereby being beneficial to a balance between the etching rate at the center region and the etching rate at the edge region on the wafer, compared with a solution that the inner coil 109 is connected between the radio frequency power source and the ground.

In the first path, the middle coil 110 is connected to the first variable capacitor 111 in parallel. In this way, the middle coil 110 and the first variable capacitor 111 are connected in parallel to form a branch, and the branch is connected to the inner coil 109 in series. A current through the inner coil 109 is a sum of currents through the middle coil 110 and the first variable capacitor 111. Compared with a solution that the middle coil 110 is directly connected to the inner coil 109 in series, power of the middle coil 110 is decreased, thereby effectively reducing the plasma concentration at the position corresponding to the middle coil 110, and thus reducing the etching rate in the middle region between the center region and the edge region on the wafer. A capacitance of the first variable capacitor 111 is variable. In this way, the actual power of the middle coil 110 can be controlled by adjusting the capacitance of the first variable capacitor 111 according to actual needs, thereby controlling the etching rate in the middle region on the wafer.

In embodiments of the present disclosure, the first path includes a second variable capacitor 106 connected to the inner coil 109 and the middle coil 110 in series, and/or, the second path includes a third variable capacitor 102 connected to the outer coil 103 in series. In this way, power distribution on the first path and the second path can be adjusted by the second variable capacitor 106 and/or the third variable capacitor 102.

In embodiments of the present disclosure, the first path includes a first current transformer 105 connected to the inner coil 109 and the middle coil 110 in series, and/or, the second path includes a second current transformer 101 connected to the outer coil 103 in series. In this way, current distribution on the first path and the second path can be monitored by the first current transformer 105 and the second current transformer 101.

In embodiments of the present disclosure, the first path includes a first ground capacitor 108 connected to the inner coil 109 and the middle coil 110 in series, and/or, the second path includes a second ground capacitor 104 connected to the outer coil 103 in series. In this way, a direct current signal in the first path can be filtered out by the first ground capacitor 108, and a direct current signal in the second path can be filtered out by the second ground capacitor 104.

In embodiments of the present disclosure, the first path includes at least one of the second variable capacitor 106, the first current transformer 105 and the first ground capacitor 108. For example, the first path includes all of the second variable capacitor 106, the first current transformer 105 and the first ground capacitor 108, as shown in FIG. 3 and FIG. 4. The second path includes at least one of the third variable capacitor 102, the second current transformer 101 and the second ground capacitor 104. For example, the second path includes all of the third variable capacitor 102, the second current transformer 101 and the second ground capacitor 104, as shown in FIG. 3 and FIG. 4.

Reference is made to FIG. 5, which is a schematic diagram showing a three-dimensional structure of an inductive coupling coil according to an embodiment of the present disclosure. The inductive coupling coil includes the inner coil 109, the middle coil 110 and the outer coil 103. The inner coil 109 includes a radio frequency connection terminal 123 and a ground connection terminal 125. The ground connection terminal 125 of the inner coil 109 is connected to a radio frequency connection terminal 125 of the middle coil 110. The middle coil 110 includes a ground connection terminal 126, and the outer coil 103 includes a radio frequency connection terminal 121 and a ground connection terminal 122. The radio frequency connection terminal 123 of the inner coil 109 and the radio frequency connection terminal 121 of the outer coil 103 are connected to the radio frequency power source. The ground connection terminal of the middle coil 110 and the ground connection terminal 122 of the outer coil 103 are connected to the ground.

In embodiments of the present disclosure, the power of the second path is reduced by the third variable capacitor 102. In addition, current is divided by the middle coil 110, and the first variable capacitor 111 connected to the middle coil 110 in parallel, such that the power of the middle coil 110 is lower than the power of the inner coil 109. In this way, an etching rate in a region affected by both of the inner coil 109 and the outer coil 103 can be decreased, without affecting etching rates at positions corresponding to the inner coil 109 and the outer coil 103.

Reference is made to FIG. 6, which is a schematic diagram showing an etching rate of a wafer according to an embodiment of the present disclosure. It can be seen from FIG. 6 that, the etching rate in the region (the region marked by the blocks in FIG. 2) affected by both of the inner coil 109 and the outer coil 103 is decreased, thereby improving the uniformity of the wafer.

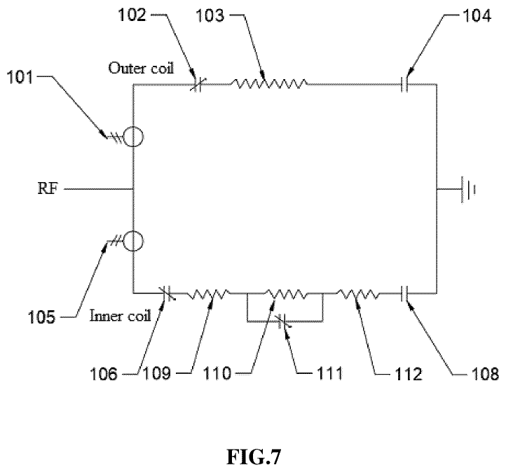

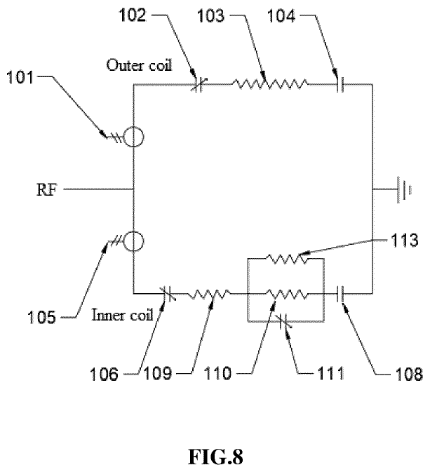

In embodiments of the present disclosure, the first path includes a first additional coil 112 connected to the inner coil 109 and the middle coil 110 in series. Reference is made to FIG. 7, which is a schematic diagram showing a circuit of another inductive coupling coil according to an embodiment of the present disclosure. The first additional coil 112 surrounds the inner coil 109 and is surrounded by the middle coil 110, that is, the first additional coil 112 is located between the inner coil 109 and the middle coil 110. Alternatively, the first additional coil 112 surrounds the middle coil 110 and is surrounded by the outer coil 103, that is, the first additional coil 112 is located between the middle coil 110 and the outer coil 103. In this way, etching rates at different positions on the wafer can be further balanced by the first additional coil 112.

It can be seen from FIG. 7 that, a first terminal of the first additional coil 112 is connected to the middle coil 110, and a second terminal of the first additional coil 112 is connected to the ground. A first terminal of the inner coil 109 is connected to the middle coil 110, and a second terminal of the inner coil 109 is connected to the radio frequency power source. In this case, the first additional coil 112 is located between the middle coil 110 and the outer coil 103, thereby facilitating wiring. Alternatively, the first terminal of the first additional coil 112 is connected to one terminal of the middle coil 110, and the second terminal of the first additional coil 112 is connected to one terminal of the inner coil 109. The other terminal of the inner coil 109 is connected to the radio frequency power source, and the other terminal of the middle coil 110 is connected to the ground. In this case, the first additional coil 112 is located between the inner coil 109 and the middle coil 110, thereby facilitating wiring.

In embodiments of the present disclosure, the first path further includes a second additional coil 113 connected to the middle coil 110 in parallel. Reference is made to FIG. 8, which is a schematic diagram showing a circuit of yet another inductive coupling coil according to an embodiment of the present disclosure. The second additional coil 113 surrounds the inner coil 109 and is surrounded by the middle coil 110, that is, the second additional coil 113 is located between the inner coil 109 and the middle coil 110. Alternatively, the second additional coil 113 surrounds the middle coil 110 and is surrounded by the outer coil 103, that is, the second additional coil 113 is located between the middle coil 110 and the outer coil 103. In this way, etching rates at different positions on the wafer can be further balanced by the second additional coil 113.

An inductive coupling coil is provided according to the embodiments of the present disclosure. The inductive coupling coil includes an inner coil, a middle coil, an outer coil and a first variable capacitor. The middle coil surrounds the inner coil, and the outer coil surrounds the middle coil. The inner coil and the middle coil are connected in series in a first path. A first terminal of the first path is connected to a radio frequency power source, and a second terminal of the first path is connected to ground. The outer coil is in a second path. A first terminal of the second path is connected to the radio frequency power source, and a second terminal of the second path is connected to the ground. That is, the inner coil and the middle coil are connected in series to form a branch, and the branch is connected to the outer coil in parallel. The middle coil and the first variable capacitor are connected in parallel. In this way, power of the middle coil is reduced, thereby reducing an etching rate in a region between the inner coil and the outer coil, and thus improving the uniformity of wafer etching.

Based on the inductive coupling coil, a radio frequency apparatus is further provided according to an embodiment of the present disclosure. The radio frequency apparatus includes a radio frequency power source, a ground terminal, and the inductive coupling coil. The radio frequency power source is configured to provide radio a frequency signal to the first terminal of the first path and the first terminal of the second path, and the ground terminal is configured to connect the second terminal of the first path and the second terminal of the second path to the ground. Power of the inner coil is lower than power of the outer coil.

Based on the inductive coupling coil, a radio frequency control method is further provided according to an embodiment of the present disclosure. The radio frequency control method includes: controlling the first variable capacitor of the inductive coupling coil to control power of the middle coil. The method may further include: controlling a second variable capacitor in the first path and/or a third variable capacitor in the second path to control power distribution on the first path and the second path.

Based on the radio frequency apparatus, a plasma processing device is further provided according to an embodiment of the present disclosure. The plasma processing device includes: a wafer holding apparatus, a process gas generating apparatus and the radio frequency apparatus. The wafer holding apparatus is configured to hold a wafer to be processed. The process gas generating apparatus is configured to generate a process gas. The radio frequency apparatus is configured to generate a high-frequency alternating magnetic field, such that the process gas forms plasma to process the wafer to be processed.

The inductive coupling coil of the radio frequency apparatus may be arranged above an insulation window at top of a plasma reaction chamber. The wafer holding apparatus may include an electrostatic chuck.

The above embodiments in this specification are described in a progressive manner. References may be made among these embodiments with respect to the same or similar portions among these embodiments, and each of the embodiments is mainly focused on describing its differences from other embodiments.

The embodiments described above are only preferred embodiments of the present disclosure. Although the present disclosure is disclosed by the above preferred embodiments, the preferred embodiments should not be interpreted as a limitation to the present disclosure. For those skilled in the art, many variations, modifications or equivalent replacements may be made to the technical solutions of the present disclosure by using the methods and technical contents disclosed above, without departing from the scope of the technical solutions of the present disclosure. Therefore, any simple modifications, equivalent replacements and modifications made to the above embodiments based on the technical essences of the present disclosure without departing from the technical solutions of the present disclosure, are deemed to fall into the protection scope of the technical solution of the present disclosure.

1. An inductive coupling coil, comprising an inner coil, a middle coil, an outer coil and a first variable capacitor, wherein
the middle coil surrounds the inner coil, and the outer coil surrounds the middle coil;
the inner coil and the middle coil are connected in series in a first path;
a first terminal of the first path is configured to be connected to a radio frequency power source, and a second terminal of the first path is configured to be connected to ground;
the middle coil is connected to the first variable capacitor in parallel;
the outer coil is in a second path; and
a first terminal of the second path is configured to be connected to the radio frequency power source, and a second terminal of the second path is configured to be connected to the ground.

2. The inductive coupling coil according to claim 1, further comprising a second variable capacitor, wherein the second variable capacitor is in the first path and is connected to the inner coil and the middle coil in series.

3. The inductive coupling coil according to claim 1, further comprising a third variable capacitor, wherein the third variable capacitor is in the second path and is connected to the outer coil in series.

4. The inductive coupling coil according to claim 1, further comprising a first current transformer, wherein the first current transformer is in the first path and is connected to the inner coil and the middle coil in series.

5. The inductive coupling coil according to claim 1, further comprising a second current transformer, wherein the second current transformer is in the second path and is connected to the outer coil in series.

6. The inductive coupling coil according to claim 1, further comprising a first additional coil, wherein
the first additional coil is in the first path and is connected to the inner coil and the middle coil in series; and
the first additional coil surrounds the inner coil and is surrounded by the middle coil.

7. The inductive coupling coil according to claim 1, further comprising a first additional coil, wherein
the first additional coil is in the first path and is connected to the inner coil and the middle coil in series; and
the first additional coil surrounds the middle coil and is surrounded by the outer coil.

8. The inductive coupling coil according to claim 6, wherein
a first terminal of the first additional coil is configured to be connected to the middle coil, and a second terminal of the first additional coil is configured to be connected to the ground; and
a first terminal of the inner coil is configured to be connected to the middle coil, and a second terminal of the inner coil is configured to be connected to the radio frequency power source.

9. The inductive coupling coil according to claim 1, further comprising a second additional coil, wherein
the second additional coil is in the first path and is connected to the middle coil in parallel; and
the second additional coil surrounds the inner coil and is surrounded by the middle coil.

10. The inductive coupling coil according to claim 1, further comprising a second additional coil, wherein
the second additional coil is in the first path and is connected to the middle coil in parallel; and
the second additional coil surrounds the middle coil and is surrounded by the outer coil.

11. The inductive coupling coil according to claim 1, further comprising a first ground capacitor, wherein the first ground capacitor is in the first path and is connected to the inner coil and the middle coil in series.

12. The inductive coupling coil according to claim 1, further comprising a second ground capacitor, wherein the second ground capacitor is in the second path and is connected to the outer coil in series.

13. The inductive coupling coil according to claim 1, wherein
the inner coil is provided with a radio frequency connection terminal and a ground connection terminal, the middle coil is provided with a radio frequency connection terminal and a ground connection terminal, and the outer coil is provided with a radio frequency connection terminal and a ground connection terminal; and
the ground connection terminal of the inner coil is configured to be connected to the radio frequency connection terminal of the middle coil, the radio frequency connection terminal of the inner coil and the radio frequency connection terminal of the outer coil are configured to be connected to the radio frequency power source, and the ground connection terminal of the middle coil and the ground connection terminal of the outer coil are configured to be connected to the ground.

14. A radio frequency apparatus, comprising the inductive coupling coil according to claim 1, a radio frequency power source and a ground terminal, wherein
the radio frequency power source is configured to provide a radio frequency signal to the first terminal of the first path and the first terminal of the second path; and
the ground terminal is configured to connect the second terminal of the first path and the second terminal of the second path to the ground.

15. The radio frequency apparatus according to claim 14, wherein power of the inner coil is lower than power of the outer coil.

16. A radio frequency control method, comprising:
controlling the first variable capacitor of the inductive coupling coil according to claim 1 to control power of the middle coil.

17. The method according to claim 16, wherein in a case that the first path of the inductive coupling coil is provided with a second variable capacitor connected to the inner coil and the middle coil in series, the method further comprises:
controlling the second variable capacitor.

18. The method according to claim 16, wherein in a case that the second path of the inductive coupling coil is provided with a third variable capacitor connected to the outer coil in series, the method further comprises:
controlling the third variable capacitor.

19. A plasma processing device, comprising a wafer holding apparatus, a process gas generating apparatus, and the radio frequency apparatus according to claim 14, wherein
the wafer holding apparatus is configured to hold a wafer to be processed;
the process gas generating apparatus is configured to generate a process gas; and
the radio frequency apparatus is configured to generate a high-frequency alternating magnetic field, wherein the process gas forms plasma to process the wafer to be processed.

20. The plasma processing device according to claim 19, wherein the inductive coupling coil of the radio frequency apparatus is arranged above an insulation window at top of a plasma reaction chamber.
